(19) United States
(12) Patent Application Publication
(10) Pub. No.: US 2025/0275046 A1
(43) Pub. Date: Aug. 28, 2025

(54) FUEL DROPLET NOZZLE ASSEMBLY

(71) Applicant: ASML Netherlands B.V., Veldhoven (NL)

(72) Inventors: Edwin Johan BUIS, Belfeld (NL); Erik Theodorus Maria BIJLAART, Someren (NL); Robertus Martinus Johannes SWINCKELS, Eindhoven (NL); Bastiaan Lambertus Wilhelmus Marinus VAN DE VEN, Rosmalen (NL)

(73) Assignee: ASML Netherlands B.V., Veldhoven (NL)

(21) Appl. No.: 18/702,508

(22) PCT Filed: Oct. 4, 2022
(86) PCT No.: PCT/EP2022/077541

§ 371 Date: Apr. 18, 2024

(30) Foreign Application Priority Data
Oct. 22, 2021 (EP) 21204119.8

(51) Int. Cl. H05G 2/00

(52) U.S. Cl. CPC H05G 2/0023; H05G 2/0082

(57) ABSTRACT

A fuel droplet nozzle assembly comprises a first hollow body and a piezoelectric element. The first hollow body comprises an inlet and an outlet and a bore extending between the inlet and the outlet. In use, fuel (for example liquid tin) may be provided into the first hollow body via the inlet under pressure. The piezoelectric element surrounds and is in direct or indirect contact with the first hollow body. In use, the piezoelectric element may be configured to squeeze the first hollow body at an excitation frequency and can be used to generate sound waves in the first hollow body. The fuel droplet nozzle assembly may further comprise a second hollow body surrounding and in direct or indirect contact with the piezoelectric element. Additionally or alternatively, the first hollow body may be a composite body formed from at least: an outer support portion formed from metal; and an inner portion formed from a glass material.

### CROSS-REFERENCE TO RELATED APPLICATIONS

This application claims priority of EP application Ser. No. 21/204,119.8 which was filed on 22 Oct. 2021 and which is incorporated herein in its entirety by reference.

### FIELD

The present invention relates to a fuel droplet nozzle assembly for producing fuel droplets and an associated method of producing fuel droplets. The fuel droplet nozzle assembly may form part of a droplet generator assembly within a laser produced plasma (LPP) radiation source. Such an LPP radiation source may produce extreme ultraviolet (EUV) radiation and may form part of, or may supply radiation to, a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

One type of radiation source for producing EUV radiation is a laser produced plasma (LPP) radiation source. In an LPP radiation source, fuel droplets, which are produced using a fuel droplet nozzle assembly, are irradiated with a laser in order to form a plasma which will emit EUV radiation. It may be desirable to provide a droplet generator assembly which at least partially addresses one or more problems in known droplet generator assemblies, whether identified herein or otherwise.

### SUMMARY

According to a first aspect of the present disclosure there is provided: a fuel droplet nozzle assembly comprising: a first hollow body comprising an inlet and an outlet and a bore extending between the inlet and the outlet; and a piezoelectric element surrounding and in direct or indirect contact with the first hollow body; wherein the first hollow body is a composite body formed from at least: an outer support portion formed from metal; and an inner portion formed from a glass material and supported by the outer support portion.

The fuel droplet nozzle assembly according to the first aspect may form part of a droplet generator assembly within a laser produced plasma (LPP) radiation source.

In use, fuel (for example liquid tin) may be provided into the first hollow body via the inlet under pressure. For example, the first hollow body may define a generally cylindrical bore between the inlet and the outlet. In general, a dimension of the outlet may be significantly smaller than a dimension of the bore defined through the first hollow body.

The fuel may exit the outlet as a spray of small fuel droplets (due to a pressure difference across the outlet). A size and separation of the small fuel droplets may be dependent on the pressure within the first hollow body and the geometry of an interior of the first hollow body. Under constant pressure, the small droplets may exit the outlet generally equally spaced and at generally the same speed. The piezoelectric element can be used to generate sound waves in the first hollow body and in fuel within the first hollow body. In particular, the piezoelectric element may be configured to squeeze the first hollow body at an excitation frequency. Advantageously, such pressure waves may cause a periodic perturbation or modulation of the exit velocities of the small fuel droplets. As a result, after a propagating a sufficient distance, this causes the small fuel droplets to clump together to form larger droplets, a frequency of the stream of larger droplets matching the excitation frequency. It is these larger fuel droplets, which will be referred to below as fuel droplets, which are irradiated with a laser beam to generate a plasma within the LPP source.

As stated above, in general, a dimension of the outlet may be significantly smaller than a dimension of the bore such that the bore may act as though the end of the bore adjacent the outlet is closed (i.e. imposing a boundary condition on the pressure waves). In particular, standing waves can be excited in fuel within the first hollow body. In some embodiments, a dimension of the inlet may be generally of the same order as a dimension of the bore such that the bore may act as though the end of the bore adjacent the inlet is open. Alternatively, in some other embodiments, a dimension of the inlet may be significantly smaller than a dimension of the bore such that the bore may act as though the end of the bore adjacent the inlet is closed.

In use, the piezoelectric element may be excited at an excitation frequency which generally matches a resonant frequency (or standing wave mode) of fuel within the bore. Furthermore, the piezoelectric element may be located such that a center, or focal point of the excitations from the piezoelectric element, generally coincides with an anti-node of the resonant mode being excited.

It will be appreciated that the first hollow body is in direct or indirect contact with an inner surface of the piezoelectric element. As will be appreciated by the skilled person, such indirect contact may be via an adhesive layer and/or an electrode but, in general, still allows for a good acoustic coupling between the piezoelectric element and the first hollow body.

The composite body of the first hollow body of the first aspect (surrounded by a piezoelectric element) is in contrast to prior art fuel droplet nozzle assemblies for droplet generator assemblies within an LPP radiation source. In one known droplet generator assembly, a generally cylindrical piezoelectric element is provided around a generally cylindrical glass tube.

As used herein, the inner portion (of the first hollow body) being supported by the outer support portion (of the first hollow body) may be intended to mean that the outer support portion is arranged to provide a reaction force to the inner portion to balance any outward forces experienced by the inner portion during use. Such outward forces may, for example, be exerted by tin within the inner portion, for example if a hydrostatic pressure of the tin is greater than an ambient pressure of an exterior of the first hollow body.

The fuel droplet nozzle assembly according to the first aspect is advantageous, as now discussed.

Advantageously, the outer metal portion allows the first hollow body to form an electrical contact for application of the excitation voltage across the entire longitudinal extent of the piezoelectric element. In addition, the inner portion (of the first hollow body) is supported by the outer support portion (of the first hollow body). Note that metals typically have a significantly higher tensile strength than glass (as used in the known fuel droplet nozzle assembly). Advantageously, in use, this may allow tin within the first hollow body to be at a significantly higher hydrostatic pressure. Furthermore, as explained above, it is desirable for a dimension of the outlet to be significantly smaller than a dimension of the bore. Typically a dimension of the bore may be or the order of 1 mm whereas the outlet may have a dimension of the order of a micron (for example 2.5 μm). Furthermore, it is desirable to have a smooth transition between the outlet and a main part of the bore. It is also desirable for the outlet to be easily cleaned as any dirt or debris can easily block the outlet. Advantageously, the use of glass for the inner portion allows for the formation of such a geometry, for example by melting the glass. Glass can also be easily cleaned.

The inner portion may be supported by the outer support portion along an entire axial extent of the inner portion.

Such an arrangement may be referred to as the inner portion being fully supported by the outer support portion.

It will be appreciated that as used herein axial is intended to mean a direction that is generally parallel to an axis of the fuel droplet nozzle assembly and that radial is intended to mean direction that is generally perpendicular to, and passes through, an axis of the fuel droplet nozzle assembly. It will be further appreciated that the axis of the fuel droplet nozzle assembly may extend along the bore extending between the inlet and the outlet (for example extend along a center of said bore).

A thickness of the outer support portion may be the same as or greater than a thickness of the inner portion.

It will be appreciated that the greater the thickness of the outer support portion the more support is provided to the inner portion to resist forces on an interior surface of the inner portion.

In some embodiments the thickness of the outer support portion may be greater than the thickness of the inner portion. In some embodiments the thickness of the outer support portion may be greater than the thickness of the inner portion by a factor of at least 2.

According to a second aspect of the present disclosure there is provided a fuel droplet nozzle assembly comprising: a first hollow body comprising an inlet and an outlet and a bore extending between the inlet and the outlet; and a piezoelectric element surrounding and in direct or indirect contact with the first hollow body; wherein the piezoelectric element comprises a hollow frustoconical body and at least a portion of an external surface of the first hollow body is generally frustoconical.

The fuel droplet nozzle assembly according to the second aspect may form part of a droplet generator assembly within a laser produced plasma (LPP) radiation source. The fuel droplet nozzle assembly according to the second aspect may be used in substantially the same way as the fuel droplet nozzle assembly according to the first aspect, as described above.

Generally, the piezoelectric element is connected to the first hollow body via an adhesive. In order to form a good acoustic coupling between the piezoelectric element and the first hollow body it is desirable to provide an even and complete layer of adhesive therebetween. In order to form a layer of adhesive between the piezoelectric element and the first hollow body adhesive may be applied to one or both surfaces and the two surfaces may be urged together to distribute the adhesive evenly so as to completely fill the space between the two surfaces. Advantageously, with the piezoelectric element comprising a frustoconical body, it is easier to urge the two surfaces of the piezoelectric element and the first hollow body together, for example by applying an axial force to the piezoelectric element. In turn, this makes it is easier to form an even and complete layer of adhesive between the piezoelectric element and the first hollow body. In addition, with such an arrangement a better acoustic coupling may be formed between the piezoelectric element and the first hollow body.

According to a third aspect of the present disclosure there is provided a fuel droplet nozzle assembly comprising: a first hollow body comprising an inlet and an outlet and a bore extending between the inlet and the outlet; and a piezoelectric element surrounding and in direct or indirect contact with the first hollow body; wherein a plurality of slits are defined on an external surface of the first hollow body, the plurality of slits extending in a direction generally parallel to the bore and extending partially radially inwards into the first hollow body.

The fuel droplet nozzle assembly according to the third aspect may form part of a droplet generator assembly within a laser produced plasma (LPP) radiation source. The fuel droplet nozzle assembly according to the third aspect may be used in substantially the same way as the fuel droplet nozzle assembly according to the first aspect, as described above.

A portion of the first hollow body which is in contact with the piezoelectric element may be formed from a metal.

Advantageously, this metal portion allows the first hollow body to form an electrical contact for application of the excitation voltage across the entire longitudinal extent of the piezoelectric element. In addition, metals typically have a significantly higher tensile strength than glass (as used in the known fuel droplet nozzle assembly). Advantageously, in use, this may allow tin within the first hollow body to be at a significantly higher hydrostatic pressure.

The portion of the first hollow body which is in contact with the piezoelectric element may be formed from molybdenum.

Advantageously, molybdenum is suitable for, and is not well wetted by, liquid tin. Therefore, for embodiments wherein the first portion is formed from molybdenum, the tin may come into direct contact with the molybdenum.

A portion of the first hollow body which defines the outlet may be formed from a glass material.

As explained above, it is desirable for a dimension of the outlet to be significantly smaller than a dimension of the bore. Typically a dimension of the bore may be or the order of 1 mm whereas the outlet may have a dimension of the order of a micron (for example 2.5 μm). Furthermore, it is desirable to have a smooth transition between the outlet and a main part of the bore. It is also desirable for the inlet to be easily cleaned as any dirt or debris can easily block the outlet. Advantageously, glass allows for the formation of such a geometry, for example by melting the glass. Glass can also be easily cleaned.

The first hollow body of fuel droplet nozzle assembly according to the second or third aspect may be a composite body formed from at least: an outer support portion formed from metal; and an inner portion formed from a glass material and supported by the outer support portion. The inner portion may be supported by the outer support portion along an entire axial extent of the inner portion. A thickness of the outer support portion may be the same as or greater than a thickness of the inner portion.

The inner portion may comprise a glass tube.

Alternatively, the inner portion may comprise: a first glass section defining the inlet; and a second glass section defining the outlet.

An outer surface of the inner portion and an inner surface of the outer support portion may be generally frustoconical at least proximate the outlet.

It will be appreciated that a frustoconical body is intended to mean a truncated conical body, i.e. the body that would be formed by removing a portion of a conical body adjacent an apex of the conical body.

An outer surface of the inner portion and an inner surface of the outer support portion may be shaped such that a pressure difference between a first region in fluid communication with the inlet and a second region in fluid communication with the outlet urges the inner and outer support portions together.

A plurality of slits may be defined on an external surface of the first hollow body, the plurality of slits extending in a direction generally parallel to the bore and extending partially radially inwards into the first hollow body.

Advantageously, these slits can allow for the hollow inner body to have an increased radial thickness for additional support, whilst increasing the flexibility of the first hollow body, improving the transmission of acoustic waves through the first hollow body. It has been found, for example, that a plurality of slits defined on an external surface of the first hollow body can increase the transmission of acoustic waves through the first hollow body by around a factor of 2.

Furthermore, the plurality of slits defined on the external surface of the intermediate body may change the radial eigen-frequency of the intermediate body. In particular, the radial eigen-frequency of the intermediate body may be dependent on the shape, depth and number of slits defined on the external surface of the intermediate body. Therefore, at least at the point of designing the intermediate body, the slits may provide a control knob which can be tuned in order to achieve a desired eigen-frequency. For example, the radial eigen-frequency of the intermediate body may be matched to an excitation frequency of the piezoelectric element.

The fuel droplet nozzle assembly may further comprise a fuel chamber in fluid communication with the inlet of the first hollow body.

The piezoelectric element may comprise a hollow frustoconical body.

It will be appreciated that, since the piezoelectric element surrounds and is in contact with the first hollow body, for such embodiments at least a portion of an external surface of the first hollow body is generally frustoconical.

Generally, the piezoelectric element is connected to the first hollow body via an adhesive. In order to form a good acoustic coupling between the piezoelectric element and the first hollow body it is desirable to provide an even and complete layer of adhesive therebetween. In order to form a layer of adhesive between the piezoelectric element and the first hollow body adhesive may be applied to one or both surfaces and the two surfaces may be urged together to distribute the adhesive evenly so as to completely fill the space between the two surfaces. Advantageously, with the piezoelectric element comprising a frustoconical body, it is easier to urge the two surfaces of the piezoelectric element and the first hollow body together, for example by applying an axial force to the piezoelectric element. In turn, this makes it is easier to form an even and complete layer of adhesive between the piezoelectric element and the first hollow body. In addition, with such an arrangement a better acoustic coupling may be formed between the piezoelectric element and the first hollow body.

The fuel droplet nozzle assembly may further comprise a second hollow body surrounding and in direct or indirect contact with the piezoelectric element. It will be appreciated that the second hollow body is in direct or indirect contact with an outer surface of the piezoelectric element. As will be appreciated by the skilled person, such indirect contact may be via an adhesive layer and/or an electrode but, in general, still allows for a good acoustic coupling between the piezoelectric element and the second hollow body. Such embodiments are particularly advantageous, as now discussed.

Advantageously, since the piezoelectric element is in contact with both the first hollow body and the second hollow body, it is fully supported on both (radially) inner and outer surfaces. This can limit tensile stress within the piezoelectric element. In addition, it can provide increased lateral stability of the first hollow body. Advantageously, this can result in a more stable and accurate pointing of fuel droplets generated by the fuel droplet nozzle assembly in use. Furthermore, such contact allows for an excitation voltage to be applied across the piezoelectric element (for example radially) such that it squeezes the first body along substantially the entire (longitudinal) extent of the piezoelectric element.

This is in contrast to prior art fuel droplet nozzle assemblies for droplet generator assemblies within an LPP radiation source. In one known droplet generator assembly, a generally cylindrical piezoelectric element is provided around a generally cylindrical glass tube.

With such a known arrangement, a periodic excitation (generally radial) voltage is applied so as to periodically squeeze the glass tube (which is filled with liquid tin). However, out of phase with the squeezing action, the piezoelectric element is subject to significant tensile stress. Over time, this can result in cracks in an external excitation electrode for the piezoelectric element, which can result in some regions of the piezoelectric element not being excited, limiting the performance of the droplet generator assembly. It may be desirable to increase a frequency of the fuel droplets within an LPP radiation source. In order to achieve this it may be desirable to increase a pressure within the fuel droplet nozzle assembly which, in turn, may lead to an increase in the thickness of the glass tube. In turn, this will result in increased tensile stress within the piezoelectric element in use.

Another problem with the known droplet generator assembly is that applying voltage across the radial inner and outer surfaces of the piezoelectric element is challenging. In order for pressure waves to be efficiently generated within the tin in the glass tube, the piezoelectric element should make a good acoustic coupling to the glass tube (via an inner electrode). In order to make an electrical contact with the inner electrode, the inner electrode of the piezoelectric element extends to the outer surface of the piezoelectric element. This limits the extent of the radially outer electrode of the piezoelectric element, limiting the (longitudinal) extent of the active part of the piezoelectric element (i.e. the part which is excited radially and which contributes to the generation of pressure waves within the tin). Furthermore, it results in stress within the piezoelectric element that has a longitudinal component.

Alternatively, the piezoelectric element may comprise a hollow cylindrical body. For such embodiments, the second hollow body may comprise a first portion having a cylindrical bore for receipt of the piezoelectric element and a generally frustoconical external surface.

With such an arrangement, if the first portion of the second hollow body is constrained such that it cannot move axially, a second portion having a complimentary generally frustoconical internal surface can be moved axially so as to urge the first portion radially inwards (towards the piezoelectric element), improving contact with the piezoelectric element.

The second hollow body may further comprise a second portion surrounding the first portion. At least a portion of an internal surface of the second portion may be generally frustoconical and complementary to the external surface of the first portion.

The second hollow body may comprise a portion having a generally frustoconical internal surface adjacent an external surface of either the piezoelectric element or the first portion of the second hollow body.

With such an arrangement, axial movement of the portion of the second hollow body having a generally frustoconical internal surface can be used to urge the piezoelectric element (either directly or via the first portion of the second hollow body) radially inwards improving contact with the piezoelectric element.

According to a fourth aspect of the present disclosure there is provided: a droplet generator assembly comprising: a fuel reservoir; and a fuel droplet nozzle assembly according to either of the first or second aspects of the present disclosure, wherein the fuel reservoir is in fluid communication with the inlet of the first hollow body.

The droplet generator assembly may further comprise a power supply arranged to apply an excitation voltage across an outer surface and an inner surface of the piezoelectric element.

The droplet generator assembly may further comprise a controller operable to control the excitation voltage applied by the power supply.

The power supply may be configured to apply a periodic excitation voltage having an excitation frequency which generally matches a resonant frequency of a fuel within the bore.

The piezoelectric element may be disposed such that a center of the piezoelectric element in a direction parallel to the bore generally coincides with an anti-node of a resonant mode of a fuel within the bore.

The droplet generator assembly may further comprise a fuel supply operable to supply fuel to the fuel reservoir.

According to a fifth aspect of the present disclosure there is provided: a laser produced plasma radiation source comprising the droplet generator assembly according to the third aspect of the present disclosure.

According to a sixth aspect of the present disclosure there is provided: a lithographic system comprising the laser produced plasma radiation source according to the fourth aspect of the present disclosure.

According to a seventh aspect of the present disclosure, there is provided: a fuel droplet nozzle assembly comprising a first hollow body comprising an inlet and an outlet and a bore extending between the inlet and the outlet; and a piezoelectric element surrounding and in direct or indirect contact with the first hollow body; wherein the first hollow body is a composite body formed from at least: an outer support portion formed from metal; and an inner portion formed from a glass material.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2A is a cross-sectional view of a first embodiment of a fuel droplet nozzle assembly according to the present disclosure which is connected to a fuel reservoir and which may form part of the radiation source shown in FIG. 1;

FIG. 2B is an exploded view of part of the fuel droplet nozzle assembly shown in FIG. 2A;

FIG. 3A is a cross-sectional view of a second embodiment of a fuel droplet nozzle assembly according to the present disclosure which is connected to a fuel reservoir and which may form part of the radiation source shown in FIG. 1;

FIG. 3B is an exploded view of part of the fuel droplet nozzle assembly shown in FIG. 3A; and

FIG. 3C is a cross-sectional view of part of the fuel droplet nozzle assembly shown in FIG. 3A.

### DETAILED DESCRIPTION

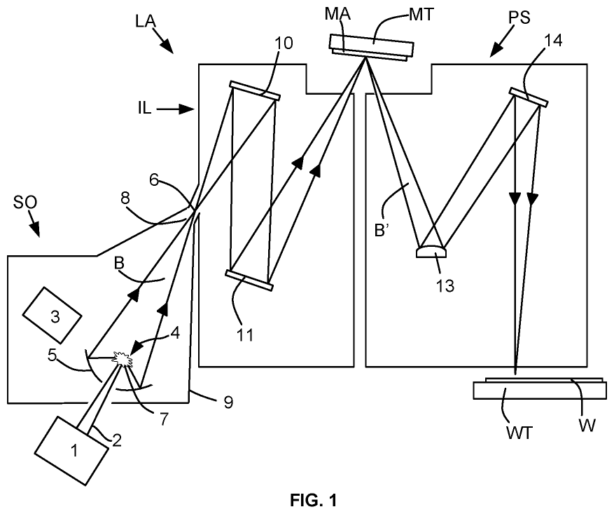

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

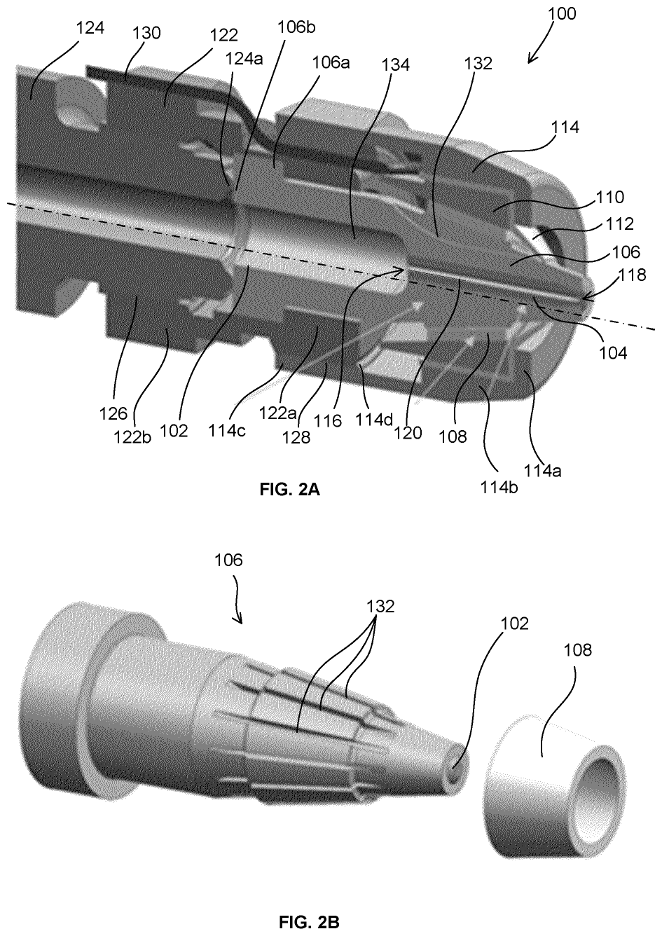

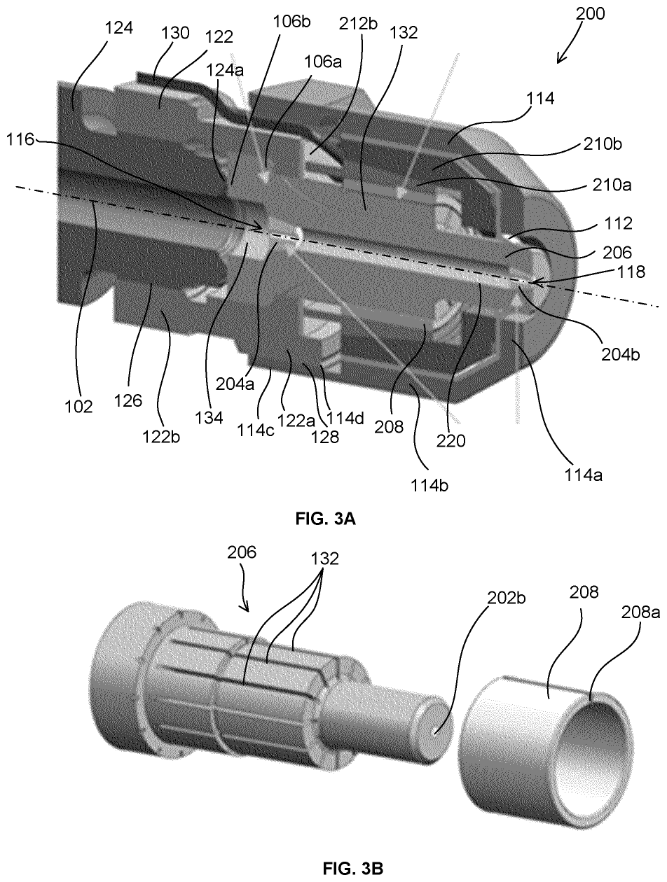

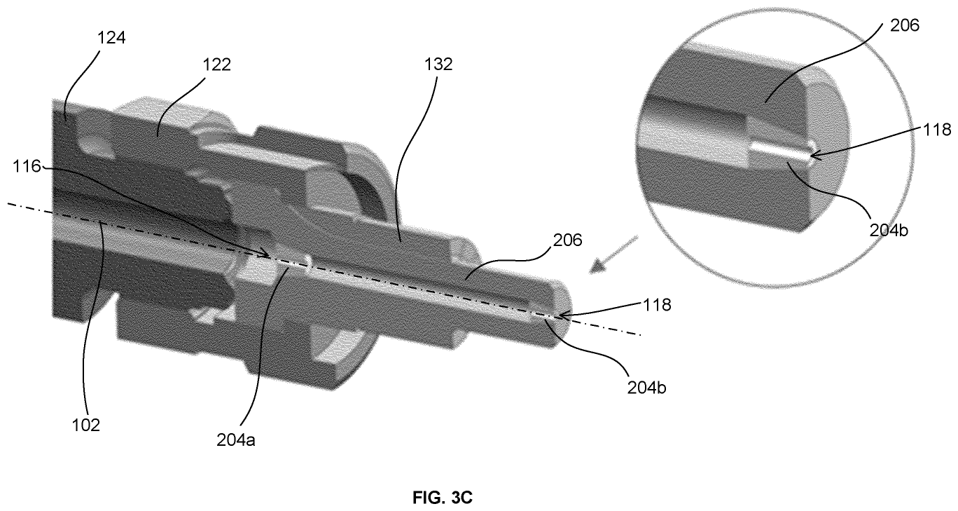

Embodiments of the present disclosure relate to novel fuel droplet nozzle assemblies that may form part of the fuel emitter 3 shown in FIG. 1 and which, in use, can be configured to direct tin, e.g. in the form of droplets, along a trajectory towards the plasma formation region 4. Two example embodiments of novel fuel droplet nozzle assemblies are now described with reference to FIGS. 2A to 3C.

FIG. 2A shows a cross-sectional view of a first embodiment of a fuel droplet nozzle assembly 100 according to the present disclosure and which may form part of the radiation source SO shown in FIG. 1. FIG. 2B is an exploded view of part of the fuel droplet nozzle assembly 100 shown in FIG. 2A.

The fuel droplet nozzle assembly 100 shown in FIG. 2A comprises a plurality of components arranged generally concentrically about an axis 102. In particular, in order moving outwards from the axis 102, the fuel droplet nozzle assembly 100 shown in FIG. 2A comprises: a glass tube 104; an intermediate body 106; a piezoelectric element 108; an outer support ring 110; an isolation member 112 and an outer body 114.

Together, the glass tube 104 and the intermediate body 106 may be considered to be a first hollow body comprising an inlet 116 and an outlet 118. In this embodiment, the inlet 116 and the outlet 118 are defined in the glass tube 104. A bore 120 defined in the glass tube 104 extends between the inlet 116 and the outlet 118.

The glass tube 104 may be formed from any suitable glass. The intermediate body 106 may be formed from a metal. For example, the intermediate body 106 may be formed from molybdenum. Advantageously, molybdenum is suitable for, and is not well wetted by, liquid tin. Therefore, for embodiments wherein the intermediate body 106 is formed from molybdenum, the tin may come into direct contact with the intermediate body 106.

For such embodiments, a layer of molybdenum oxide may be provided between the glass tube 104 and the intermediate body 106, which may improve a bond between the glass tube 104 and the intermediate body 106.

The piezoelectric element 108 surrounds and is in direct or indirect contact with the intermediate body 106 of the first hollow body.

The intermediate body 106 and the piezoelectric element 108 may be bonded together using a solder. The solder may, for example, comprise a gold solder or a silver solder. The solder may be suitable for operation at typical operating temperatures of the fuel droplet nozzle assembly 100, which may be, for example, slightly above a melting point of a fuel such as, for example, tin. Tin has a melting point of around 232° C. A suitable solder for use with tin as a fuel may, for example, be the alloy Indalloy 177 as marketed by Indium Corporation, a company incorporated in the US.

In order to achieve a good bond between the intermediate body 106 and the piezoelectric element 108, a solder compatibility layer may be provided on the intermediate body 106 and/or the piezoelectric element 108. In embodiments wherein the intermediate body 106 is formed from molybdenum, the intermediate body 106 may be provided with a solder compatibility layer comprising nickel and/or gold. The solder compatibility layer may be provided on the intermediate body 106 using any suitable method such as, for example, sputtering.

The outer support ring 110 may be considered to be a second hollow body surrounding and in direct or indirect contact with the piezoelectric element 108. The second hollow body may further be considered to comprise the isolation member 112 and the outer body 114.

The outer support ring 110 may be formed from a metal. For example, the outer support ring 110 may be formed from molybdenum.

The piezoelectric element 108 and the outer support ring 110 may be bonded together using a solder. The solder may, for example, comprise a gold solder or a silver solder. The solder may be suitable for operation at typical operating temperatures of the fuel droplet nozzle assembly 100, which may be, for example, slightly above a melting point of a fuel such as, for example, tin. Tin has a melting point of around 232° C. A suitable solder for use with tin as a fuel may, for example, be the alloy Indalloy 177 as marketed by Indium Corporation, a company incorporated in the US.

In order to achieve a good bond between the piezoelectric element 108 and the outer support ring 110, a solder compatibility layer may be provided on the piezoelectric element 108 and/or the outer support ring 110. In embodiments wherein the outer support ring 110 is formed from molybdenum, the outer support ring 110 may be provided with a solder compatibility layer comprising nickel and/or gold. The solder compatibility layer may be provided on the outer support ring 110 using any suitable method such as, for example, sputtering.

The isolation member 112 generally fills a space between the intermediate body 106 and the outer body 114. The isolation member 112 may be formed from an insulating material. The isolation member 112 may be formed from a plastics material that is suitable for operation at typical operating temperatures of the fuel droplet nozzle assembly 100, which may be, for example, slightly above a melting point of a fuel such as, for example, tin. The isolation member 112 may be formed from polyimides.

The outer body 114 may be formed from a material suitable for operation in the environment within the enclosing structure 9 of the radiation source SO. For example, the outer body 114 may be formed from molybdenum.

In this embodiment, the fuel droplet nozzle assembly 100 further comprises an engagement member 122 that facilitates engagement of the fuel droplet nozzle assembly 100 to a fuel reservoir 124, as now discussed.

The engagement member 122 is generally cylindrical and hollow. A bore through the engagement member 122 is stepped. In particular, the engagement member 122 comprises a first portion 122a having a smaller diameter bore and a second portion 122b having a larger diameter bore. Between the first portion 122a and the second portion 122b is defined a generally annular surface, or internal shoulder.

Furthermore, the intermediate body 106 is provided with an external flange 106a at an axial end of the intermediate body that is distal the outlet 118. The external flange 106a defines a generally annular surface, or external shoulder.

An external dimension of the intermediate body 106 is smaller than an internal dimension of the second portion 122a the engagement member 122.

With the exception of the external flange 106a, an external dimension of the intermediate body 106 is smaller than an internal dimension of the first portion 122a the engagement member 122. However, an external dimension of the external flange 106a of the intermediate body 106 is larger than an internal dimension of the first portion 122a the engagement member 122.

The intermediate body 106 is partially received in the engagement member 122 as follows. The intermediate body 106 is inserted through the second portion 122b of the engagement member 122. The intermediate body 106 is further inserted through the first portion 122a of the engagement member 122 until the external flange 106a abuts the generally annular surface defined between the first portion 122a and the second portion 122b.

The engagement member 122 forms an extension of the intermediate body 106, extending axially (relative to axis 102) away from the outlet 118. The second portion 122b of the engagement member 122 is generally cylindrical and is arranged for engagement with a generally cylindrical portion of fuel reservoir 124 at an engagement interface 126. For example, the second portion 122b of the engagement member 122 may be provided with an internal thread and an external surface of the generally cylindrical portion of fuel reservoir 124 may define a complementary thread. Alternatively, an internal surface of the second portion 122b of the engagement member 122 may be welded, brazed, soldered or otherwise adhered to an external surface of the generally cylindrical portion of fuel reservoir 124. As the fuel reservoir 124 is inserted into the second portion 122b of the engagement member 122 and engages therewith, an axial end portion 124a of the fuel reservoir 124 urges the external flange 106a into contact with the generally annular surface defined between the first portion 122a and the second portion 122b.

In some embodiments, the engagement member 122 may be formed from molybdenum.

It will be appreciated that in an alternative embodiment the intermediate body 106 and the engagement member 122 may be formed from a single integrally formed body.

The fuel reservoir 124 is in fluid communication with the inlet 116 defined by the glass tube 104. Together, the fuel droplet nozzle assembly 100 and the fuel reservoir 124 may be considered to be a droplet generator assembly. It will be appreciated that tin may be supplied to the fuel reservoir 124 from another fuel reservoir (not shown). The fuel reservoir 124 may comprise a fuel filter (not shown). For such embodiments, it may be desirable to seal the filter to in internal surface of the fuel reservoir 124. The interface between the intermediate body 106 and the engagement member 122 may allow for one or more seals or glands to seat a fuel filter body to an internal surface formed in the intermediate body 106 and the engagement member 122.

Any metal components of the droplet generator assembly which, in use, will come into contact with liquid tin such as the intermediate body 106 and the fuel reservoir 124 may be formed from molybdenum since molybdenum is not easily wetted by tin. In principle, other metal components of the droplet generator assembly which, in use, do not come into contact with liquid tin may be formed from other metals. Such components which, in use, do not come into contact with liquid tin may include: the outer support ring 110; the engagement member 122; and the outer body 114. However, it may be desirable to also form such components (which, in use, do not come into contact with liquid tin) from molybdenum. Advantageously, this may reduce variations in the coefficient of thermal expansion over the droplet generator assembly which, in turn, may avoid, or at least reduce, temperature related stress fluctuations within the droplet generator assembly. Such stress may otherwise be experienced if components are formed from different materials resulting in different thermal expansion properties since the droplet generator assembly will typically operate above a melting point of a fuel such as, for example, tin.

It will be appreciated that the droplet generator assembly may further comprise a power supply arranged to apply an excitation voltage across an outer surface and an inner surface of the piezoelectric element 108. Furthermore, the droplet generator assembly may further comprise a controller operable to control the excitation voltage applied by the power supply. The power supply may be configured to apply a periodic excitation voltage having an excitation frequency which generally matches a resonant frequency of a fuel within the bore 120.

In some embodiments, the piezoelectric element 108 may be disposed such that a center of the piezoelectric element 108 in a direction parallel to the bore 120 (i.e. a position along axis 102) generally coincides with an anti-node of a resonant mode of a fuel within the bore 120.

The outer body 114 is generally cylindrical and hollow. A bore through the outer body 114 is stepped. In particular, the outer body 114 comprises a first portion 114a having a smaller diameter bore and a second portion 114b having a larger diameter bore. Between the first portion 114a and the second portion 114b is defined a generally annular surface, or internal shoulder. The shoulder defined between the first portion 114a and the second portion 114b is shaped and sized to receive a portion of the outer support ring 110 and the isolation member 112.

The outer body 114 further comprises a third portion 114c having a larger diameter bore than the second portion 114b. The third portion 114c of the outer body 114 is generally cylindrical and is arranged for engagement with a generally cylindrical portion of the engagement member 122 at an engagement interface 128. For example, an internal surface of the third portion 114c of the outer body 114 may be welded, brazed, soldered or otherwise adhered to an external surface of the engagement member 122. A location feature 114d may be formed on an internal surface of the third portion 114c of the outer body 114 to facilitate accurate alignment of the outer body 114 and the engagement member 122.

The fuel droplet nozzle assembly 100 further comprises an isolated connection wire 130. The wire 130 is connected to the outer support ring 110.

Note that the otherwise generally matching, mating cylindrical surfaces of the third portion 114c of the outer body 114 and the engagement member 122 (at engagement interface 128) are shaped so as to allow the wire 130 to extend from the outer support ring 110 to a voltage supply (not shown).

The wire 130 provides an electrical connection with an exterior surface of the piezoelectric element 108. Electrical connection to an interior surface of the piezoelectric element 108 may be achieved via the intermediate body 106 either directly or indirectly via any other conducting body or bodies in contact with the intermediate body 106. Note that the outer support ring 110 does not contact any other element of the fuel droplet nozzle assembly 100 other than the isolation member 112, which electrically isolates the outer support ring 110 from other parts of the fuel droplet nozzle assembly 100. Note that the location feature 114d formed on the internal surface of the third portion 114c of the outer body 114 may be positioned so as to ensure that the outer support ring does not contact the engagement member 122.

The fuel droplet nozzle assembly 100 according to the first aspect may form part of a droplet generator assembly within a laser produced plasma (LPP) radiation source, such as the radiation source SO in FIG. 1.

In use, fuel (for example liquid tin) may be provided into the generally cylindrical bore 120 between the inlet 116 and the outlet 118. In general, a dimension of the outlet 118 may be significantly smaller than a dimension of the bore 120 defined through the glass tube 104.

The fuel may exit the outlet as a spray of small fuel droplets (due to a pressure difference across the outlet 118). A size and separation of the small fuel droplets may be dependent on the pressure within the glass tube 104 and the geometry of an interior of the glass tube 104. Under constant pressure, the small droplets may exit the outlet generally equally spaced and at generally the same speed. The piezoelectric element 108 can be used to generate sound waves in fuel within the glass tube 104. In particular, the piezoelectric element 108 may be configured to squeeze the first hollow body (formed by the glass tube 104 and the intermediate body 106) at an excitation frequency. Advantageously, such pressure waves may cause a periodic perturbation or modulation of the exit velocities of the small fuel droplets. As a result, after a propagating a sufficient distance, this causes the small fuel droplets to clump together to form larger droplets, a frequency of the stream of larger droplets matching the excitation frequency. It is these larger fuel droplets, which will be referred to below as fuel droplets, which are irradiated with the laser beam 2 to generate a plasma within the radiation source SO.

As stated above, in general, a dimension of the outlet 118 may be significantly smaller than a dimension of the bore 120 such that the bore 120 may act as though the end of the bore 120 adjacent the outlet 118 is closed (i.e. imposing a boundary condition on the pressure waves). In particular, standing waves can be excited in fuel within the bore 120. In this embodiments, a dimension of the inlet 116 is generally of the same order as a dimension of the bore 120 such that the bore 120 acts as though the end of the bore 120 adjacent the inlet 116 is open.

In use, the piezoelectric element 108 may be excited at an excitation frequency which generally matches a resonant frequency (or standing wave mode) of fuel within the bore 120. Furthermore, the piezoelectric element 108 may be located such that a center, or focal point of the excitations from the piezoelectric element, generally coincides with an anti-node of the resonant mode being excited.

As stated above, in this embodiment, a dimension of the inlet 116 is generally of the same order as a dimension of the bore 120 such that the bore 120 acts as though the end of the bore 120 adjacent the inlet 116 is open whereas a dimension of the outlet 118 may be significantly smaller than a dimension of the bore 120 such that the bore 120 may act as though the end of the bore 120 adjacent the outlet 118 is closed. Therefore, standing waves may be excited in fuel within the bore 120 such that there is a node at the inlet 116 and an antinode at the outlet 118. As a result, standing waves can be excited such that the length of the bore 120 is equal to the wavelength of the standing wave multiplied by ¼, ¾, 5/4 etc. In general, standing waves can be excited such that the length of the bore 120 is equal to the wavelength of the standing wave multiplied by (1+2n)/4, where n is an integer (i.e. n=0, 1, 2 . . . ). The embodiment shown in FIG. 2A is configured to excite standing waves such that the length of the bore 120 is equal to the wavelength of the standing wave multiplied by ¾. Furthermore, a center of the piezoelectric element 106 (in the axial direction) generally points at an anti-node of this standing wave (which may be disposed approximately ⅓ of the way from the inlet 116 to the outlet 118. A driving frequency of the piezoelectric element is matched to the frequency of this standing wave (the frequency of this standing wave is given by the speed of sound in the fuel within the bore 120 divided by the wavelength of the standing wave).

The fuel droplet nozzle assembly 100 is advantageous over existing arrangements, as now discussed.

Advantageously, since the piezoelectric element 108 in contact with both the first hollow body (formed by the glass tube 104 and intermediate body 106) and the second hollow body (formed at least by the outer support ring 110), it is fully supported on both (radially) inner and outer surfaces. This can limit tensile stress within the piezoelectric element 108. In addition, it can provide increased lateral stability of the first hollow body (formed by the glass tube 104 and intermediate body 106).

Advantageously, this can result in a more stable and accurate pointing of fuel droplets generated by the fuel droplet nozzle assembly 100 in use. Furthermore, such contact allows for an excitation voltage to be applied across the piezoelectric element 108 (for example radially) such that it squeezes the first body along substantially the entire (longitudinal or axial) extent of the piezoelectric element 108.

This is in contrast to prior art fuel droplet nozzle assemblies for droplet generator assemblies within an LPP radiation source. In one known droplet generator assembly, a generally cylindrical piezoelectric element is provided around a generally cylindrical glass tube.

With such a known arrangement, a periodic excitation (generally radial) voltage is applied so as to periodically squeeze the glass tube (which is filled with liquid tin). However, out of phase with the squeezing action, the piezoelectric element is subject to significant tensile stress. Over time, this can result in cracks in an external excitation electrode for the piezoelectric element, which can result in some regions of the piezoelectric element not being excited, limiting the performance of the droplet generator assembly. It may be desirable to increase a frequency of the fuel droplets within an LPP radiation source. In order to achieve this it may be desirable to increase a pressure within the fuel droplet nozzle assembly which, in turn, may lead to an increase in the thickness of the glass tube. In turn, this will result in increased tensile stress within the piezoelectric element in use.

Another problem with the known droplet generator assembly is that applying voltage across the radial inner and outer surfaces of the piezoelectric element is challenging. In order for pressure waves to be efficiently generated within the tin in the glass tube, the piezoelectric element should make a good acoustic coupling to the glass tube (via an inner electrode). In order to make an electrical contact with the inner electrode, the inner electrode of the piezoelectric element extends to the outer surface of the piezoelectric element. This limits the extent of the radially outer electrode of the piezoelectric element, limiting the (longitudinal) extent of the active part of the piezoelectric element (i.e. the part which is excited radially and which contributes to the generation of pressure waves within the tin). Furthermore, it results in stress within the piezoelectric element that has a longitudinal component.

In the fuel droplet nozzle assembly 100 shown in FIG. 2A, the first hollow body which is in direct or indirect contact with the piezoelectric element 108 is a composite body formed from at least: an outer support portion (intermediate body 106) formed from metal; and an inner portion (glass tube 104) formed from a glass material. The inner portion (glass tube 104) is supported by the outer support portion (intermediate body 106). As used herein, glass tube 104 being supported by the intermediate body 106 means that the intermediate body 106 is arranged to provide a reaction force to the glass tube 104 to balance any outward forces experienced by the glass tube 104 during use. Such outward forces may, for example, be exerted by tin within the bore 120 under a hydrostatic pressure that is greater than an ambient pressure of an exterior of the glass tube 104.

Such a composite first hollow body (surrounded by the piezoelectric element 108) is in contrast to prior art fuel droplet nozzle assemblies for droplet generator assemblies within an LPP radiation source. In one known droplet generator assembly, a generally cylindrical piezoelectric element is provided around a generally cylindrical glass tube.

Advantageously, the outer metal portion of intermediate body 106 allows the first hollow body to form an electrical contact for application of the excitation voltage across the entire longitudinal extent of the piezoelectric element 108. In addition, the glass tube 104 is supported by the (metal) intermediate body 106. Note that metals typically have a significantly higher tensile strength than glass (as used in the known fuel droplet nozzle assembly). Advantageously, in use, this may allow tin within the first hollow body to be at a significantly higher hydrostatic pressure. Furthermore, as explained above, it is desirable for a dimension of the outlet 118 to be significantly smaller than a dimension of the bore 120. Typically a dimension of the bore 120 may be or the order of 1 mm whereas the outlet 118 may have a dimension of the order of a micron (for example 2.5 μm). Furthermore, it is desirable to have a smooth transition between the outlet 118 and a main part of the bore 120. It is also desirable for the inlet 116 and outlet 118 to be easily cleaned as any dirt or debris can easily block the outlet 118. Advantageously, the use of glass for the inner portion allows for the formation of such a geometry, for example by melting the glass. Glass can also be easily cleaned.

Note that the glass tube 104 is supported by the intermediate body 106 along an entire axial extent of the glass tube 104. Such an arrangement may be referred to as the glass tube 104 being fully supported by the intermediate body 106.

In this embodiment, a thickness of the intermediate body 106 is greater than a thickness of the glass tube 104 by a factor of at least 2. It will be appreciated that the greater the thickness of the intermediate body 106 the more support is provided to the glass tube 104 to resist forces on an interior surface of the glass tube 104 (from within the bore 120). In general, a thickness of the intermediate body 106 may be the same as or greater than a thickness of the glass tube 104.

As can be seen from FIG. 2A, proximate the outlet 118, an outer surface of the glass tube 104 and an inner surface of the intermediate body 106 are generally frustoconical, with the glass tube tapering in a direction such that an outer diameter of the glass tube becomes smaller nearer to the outlet 118. It will be appreciated that a frustoconical body is intended to mean a truncated conical body, i.e. the body that would be formed by removing a portion of a conical body adjacent an apex of the conical body.

As a result of these frustoconical portions of the outer surface of the glass tube 104 and inner surface of the intermediate body 106 proximate the outlet 118, a pressure difference between a first region in fluid communication with the inlet 116 and a second region in fluid communication with the outlet 118 urges the glass tube 104 towards the intermediate body 106.

As can be best seen in FIG. 2B, a plurality of slits 132 are defined on an external surface of the intermediate body 106 (one of these slits is visible in FIG. 2A). The plurality of slits 132 extend in a direction generally parallel to the bore 120 (i.e. generally along axis 102) and extend partially radially inwards into the intermediate body 106, towards the glass tube 104.

Advantageously, these slits 132 can allow for the hollow inner body (formed by the glass tube 104 and intermediate body 106) to have an increased radial thickness for additional support, whilst increasing the flexibility of the first hollow body, improving the transmission of acoustic waves through the first hollow body. It has been found, for example, that a plurality of slits 132 defined on an external surface of the first hollow body can increase the transmission of acoustic waves through the first hollow body by around a factor of 2.

Furthermore, the plurality of slits 132 defined on the external surface of the intermediate body 106 change the radial eigen frequency of the intermediate body 106. In particular, the radial eigen frequency of the intermediate body 106 is dependent on the shape, depth and number of slits 132 defined on the external surface of the intermediate body 106. Therefore, at least at the point of designing the intermediate body 106, the slits provide a control knob which can be tuned in order to achieve a desired eigen frequency. For example, the radial eigen frequency of the intermediate body 106 may be matched to an excitation frequency of the piezoelectric element 108.

The fuel droplet nozzle assembly 100 further comprises a fuel chamber 134 in fluid communication with the inlet 116. The fuel chamber 134 is formed by an interior of the intermediate member 106. In particular, the intermediate member 106 comprises a portion for receipt of the glass tube 104 having internal dimensions and shape that generally match external dimensions and shape of the glass tube 104. In addition, the intermediate member 106 comprises another portion having a larger internal dimension than the portion for receipt of the glass tube 104, which defines the fuel chamber 134.

In this embodiment, the piezoelectric element 108 comprises a hollow frustoconical body. Similarly, a portion of an external surface of the intermediate body 106 that contacts the piezoelectric element 108 is generally frustoconical and a portion of an internal surface of the outer support ring 110 that contacts the piezoelectric element 108 is generally frustoconical.

As explained above, generally, the piezoelectric element 108 is connected to the intermediate body 106 and the outer support ring 110 via an adhesive (for example solder). In order to form a good acoustic coupling between the piezoelectric element 108 and both the intermediate body 106 and the outer support ring 110 it is desirable to provide an even and complete layer of adhesive therebetween. In order to form such a layer of adhesive between the piezoelectric element and another body (either the intermediate body 106 or the outer support ring 110) adhesive may be applied to one or both surfaces and the two surfaces may be urged together to distribute the adhesive evenly so as to completely fill the space between the two surfaces. Advantageously, with the piezoelectric element 108 comprising a frustoconical body, it is easier to urge the surfaces of the piezoelectric element 108 and the intermediate body 106 together, for example by applying an axial force to the piezoelectric element 108. Furthermore, it is easier to urge the surfaces of the piezoelectric element 108 and the outer support ring 110 together, for example by applying an axial force to the outer support ring 110. In turn, this makes it is easier to form an even and complete layer of adhesive between the piezoelectric element and each of: the intermediate body 106; and the outer support ring 110. In addition, with such an arrangement a better acoustic coupling may be formed between the piezoelectric element 108 and the intermediate body 106.

FIG. 3A shows a cross-sectional view of a second embodiment of a fuel droplet nozzle assembly 200 according to the present disclosure and which may form part of the radiation source SO shown in FIG. 1. FIG. 3B is an exploded view of part of the fuel droplet nozzle assembly 200 shown in FIG. 3A and FIG. 3C is a cross-sectional view of part of the fuel droplet nozzle assembly 200 shown in FIG. 3A.

The fuel droplet nozzle assembly 200 shown in FIG. 3A shares several features in common with the fuel droplet nozzle assembly 100 shown in FIG. 2A. In the following only the differences between fuel droplet nozzle assembly 200 shown in FIG. 3A and the fuel droplet nozzle assembly 100 shown in FIG. 2A will be described in detail. Any features of the fuel droplet nozzle assembly 200 shown in FIG. 3A that are generally structurally and functionally equivalent to corresponding features of the fuel droplet nozzle assembly 100 shown in FIG. 2A share common reference numerals therewith. Any features of the fuel droplet nozzle assembly 200 shown in FIG. 3A that are generally equivalent to, but materially different either in structure or function from, corresponding features of the fuel droplet nozzle assembly 100 shown in FIG. 2A generally have reference numerals that are given by the reference numeral of the equivalent feature plus 100.

The fuel droplet nozzle assembly 200 shown in FIG. 3A also comprises a first hollow body (surrounded by and in direct or indirect contact with the piezoelectric element 208) that is a composite body formed from at least: an outer support portion 206 formed from metal; and an inner portion formed from a glass material 204a, 204b.

A first material difference is that, rather than a glass tube 104, the inner portion comprises: a first glass section 204a defining the inlet 116; and a second glass section 204b defining the outlet 118. A second difference is that the bore 220 is defined in the intermediate member 206. In this embodiment.

a dimension of the inlet 116 may be smaller than a dimension of the bore 220 such that the bore 220 may act as though the end of the bore 220 adjacent the inlet 116 is closed. For example, a dimension of the inlet 116 may be of the order of 0.5 mm, a dimension of the bore 220 may be of the order of 2 mm and a dimension of the outlet 118 may be of the order of 2.5 μm.

The first and second glass sections 204a, 204b are supported by the intermediate body 206.

Note that the first and second glass sections 204a, 204b are supported by the intermediate body 206 along their entire axial extents. In this embodiment, a thickness of the intermediate body 206 is greater than a thickness of the first and second glass sections 204a, 204b by a factor of at least 2.

With this embodiment, pressure waves from the piezoelectric element 208 only pass through the intermediate body 206 before being transmitted to the fuel within the bore. In particular, there is no interface between a metal (for example molybdenum) and glass as there is in the embodiment of the fuel droplet nozzle assembly 100 shown in FIG. 2A (between intermediate body 106 and glass tube 104). This may be advantageous if, for example, it is difficult to achieve a good acoustic coupling between metal and glass with little acoustic loss at the coupling.

As stated above, in this embodiment, a dimension of both the inlet 116 and the outlet 118 is generally smaller than a dimension of the bore 120 such that the bore 120 may act as though both ends of the bore 120 are closed. Therefore, standing waves may be excited in fuel within the bore 120 such that there is an antinode at the inlet 116 and an antinode at the outlet 118. As a result, standing waves can be excited such that the length of the bore 120 is equal to the wavelength of the standing wave multiplied by 2/4, 4/4, 6/4 etc. In general, standing waves can be excited such that the length of the bore 120 is equal to the wavelength of the standing wave multiplied by 2n/4, where n is an integer (i.e. n=0, 1, 2, . . . ). The embodiment shown in FIG. 3A is configured to excite standing waves such that the length of the bore 120 is equal to the wavelength of the standing wave multiplied by 4/4. Furthermore, a center of the piezoelectric element 106 (in the axial direction) generally points at an anti-node of this standing wave (which may be disposed approximately ½ of the way from the inlet 116 to the outlet 118. A driving frequency of the piezoelectric element is matched to the frequency of this standing wave (the frequency of this standing wave is given by the speed of sound in the fuel within the bore 120 divided by the wavelength of the standing wave).

A second difference is that the piezoelectric element 208 comprises a hollow cylindrical body. Similarly, an exterior surface of the intermediate body 206 and an internal surface of an inner portion of the outer support ring are generally cylindrical rather than frustoconical. Furthermore, to allow movement so as to allow the piezoelectric element 208 to be clamped onto intermediate body 206, the piezoelectric element 208 is provided with an axial slit 208a.

An advantage of a piezoelectric element 208 comprising a hollow cylindrical body is that such a piezoelectric element 208 may be easier to manufacture.

A third difference is that the outer support ring is replaced by: a first portion 210a having a cylindrical bore for receipt of the piezoelectric element 208 and a generally frustoconical external surface; and second portion 210b which is intermediate to the isolation member 112 and the first portion 210a.

With such an arrangement, even though the piezoelectric element does not have a frustoconical shape, if the first portion 210a of the outer support ring is constrained such that it cannot move axially, the second portion 210b, which has a complimentary generally frustoconical internal surface can be moved axially so as to urge the first portion 210a radially inwards (towards the piezoelectric element 208), improving contact with the piezoelectric element 208.

The first portion 210a of the outer support ring is constrained such that it cannot move axially by physically contacting an additional, generally annular isolation member 212b is provided between the first portion 210a of the support ring and the attachment member 122.

It will be appreciated that alternative embodiments of fuel droplet nozzle assemblies may share a mixture of the features of embodiments of fuel droplet nozzle assemblies 100, 200 described above. For example, one alternative embodiment of a fuel droplet nozzle assembly may be generally of the form of the fuel droplet nozzle assembly 100 shown in FIG. 2A but rather than a glass tube 104, the inner portion may comprise: a first glass section 204a defining the inlet 116; and a second glass section 204b defining the outlet 118, as in the fuel droplet nozzle assembly 200 shown in FIG. 3A. That is, this other embodiment may only differ from the fuel droplet nozzle assembly 100 shown in FIG. 2A by the above-mentioned first material difference.

The above-described embodiments of fuel droplet nozzle assemblies 100, 200 both comprise a second hollow body surrounding and in direct or indirect contact with the piezoelectric element. In addition, in both of the above-described embodiments of fuel droplet nozzle assemblies 100, 200 the first hollow body is a composite body formed from at least: an outer support portion formed from metal; and an inner portion formed from a glass material. However, it will be appreciated that, alternative embodiments may not have both of these features. Rather, in some alternative embodiments, the fuel droplet nozzle assembly may either (a) comprise a second hollow body surrounding and in direct or indirect contact with the piezoelectric element; or (b) have a first hollow body that is a composite body formed from at least: an outer support portion formed from metal; and an inner portion formed from a glass material.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

In order to illustrate certain possible combinations of embodiments, the following clauses are given, without limiting the combinations thereof which arise directly and unambiguously from the above description.

### CLAUSES

1. A fuel droplet nozzle assembly comprising:
   a first hollow body comprising an inlet and an outlet bore extending between the inlet and the outlet;
   a piezoelectric element surrounding and in direct or indirect contact with the first hollow body; and
   a second hollow body surrounding and in direct or indirect contact with the piezoelectric element.
2. A fuel droplet nozzle assembly comprising:
   a first hollow body comprising an inlet and an outlet and a bore extending between the inlet and the outlet; and
   a piezoelectric element surrounding and in direct or indirect contact with the first hollow body; wherein the first hollow body is a composite body formed from at least:
an outer support portion formed from metal; and
an inner portion formed from a glass material.
3. The fuel droplet nozzle assembly of clause 1 wherein a portion of the first hollow body which is in contact with the piezoelectric element is formed from a metal.
4. The fuel droplet nozzle assembly of clause 2 or clause 3 wherein the portion of the first hollow body which is in contact with the piezoelectric element is formed from molybdenum.
5. The fuel droplet nozzle assembly of any preceding clause wherein a portion of the first hollow body which defines the outlet is formed from a glass material.
6. The fuel droplet nozzle assembly of any preceding clause when dependent either directly or indirectly on clause 1 wherein the first hollow body is a composite body formed from at least:
   an outer support portion formed from metal; and
   an inner portion formed from a glass material.
7. The fuel droplet nozzle assembly of clause 2 or clause 6 wherein the inner portion comprises a glass tube.
8. The fuel droplet nozzle assembly of clause 2 or clause 6 wherein the inner portion comprises:
   a first glass section defining the inlet; and
   a second glass section defining the outlet.
9. The fuel droplet nozzle assembly of any one of clauses 2, 6, 7 or 8 wherein an outer surface of the inner portion and an inner surface of the outer support portion are generally frustoconical at least proximate the outlet.
10. The fuel droplet nozzle assembly of any one of clauses 2, 6, 7, 8 or 9 wherein an outer surface of the inner portion and an inner surface of the outer support portion are shaped such that a pressure difference between a first region in fluid communication with the inlet and a second region in fluid communication with the outlet urges the inner and outer support portions together.
11. The fuel droplet nozzle assembly of any preceding clause wherein a plurality of slits are defined on an external surface of the first hollow body, the plurality of slits extending in a direction generally parallel to the bore and extending partially radially inwards into the first hollow body.
12. The fuel droplet nozzle assembly of any preceding clause further comprising a fuel chamber in fluid communication with the inlet of the first hollow body.
13. The fuel droplet nozzle assembly of any preceding clause wherein the piezoelectric element comprises a hollow frustoconical body.
14. The fuel droplet nozzle assembly of any preceding clause when dependent either directly or indirectly on clause 1 wherein the piezoelectric element comprises a hollow cylindrical body and wherein the second hollow body comprises a first portion having a cylindrical bore for receipt of the piezoelectric element and a generally frustoconical external surface.
15. The fuel droplet nozzle assembly of clause 14 wherein the second hollow body further comprises a second portion surrounding the first portion and wherein at least a portion of an internal surface of the second portion is generally frustoconical and complementary to the external surface of the first portion.
16. The fuel droplet nozzle assembly of any one of clauses 13 to 15 when dependent either directly or indirectly on clause 1 wherein the second hollow body comprises a portion having a generally frustoconical internal surface adjacent an external surface of either the piezoelectric element or the first portion of the second hollow body.
17. A droplet generator assembly comprising:
   a fuel reservoir; and
   a fuel droplet nozzle assembly according to any preceding claim, wherein the fuel reservoir is in fluid communication with the inlet of the first hollow body.
18. The droplet generator assembly of clause 17 further comprising a power supply arranged to apply an excitation voltage across an outer surface and an inner surface of the piezoelectric element.
19. The droplet generator assembly of clause 18 further comprising a controller operable to control the excitation voltage applied by the power supply.
20. The droplet generator assembly of either of clauses 18 or 19 wherein the power supply is configured to apply a periodic excitation voltage having an excitation frequency which generally matches a resonant frequency of a fuel within the bore.
21. The droplet generator assembly of any one of clauses 17 to 20 wherein the piezoelectric element is disposed such that a center of the piezoelectric element in a direction parallel to the bore generally coincides with an anti-node of a resonant mode of a fuel within the bore.
22. The droplet generator assembly of any one of clauses 17 to 21 further comprising a fuel supply operable to supply fuel to the fuel reservoir.
23. A laser produced plasma radiation source comprising the droplet generator assembly of any one of clauses 18 to 22.
24 A lithographic system comprising the laser produced plasma radiation source of clause 23.

1.-16. (canceled)

17. A fuel droplet nozzle assembly comprising:
a first hollow body comprising an inlet and an outlet and a bore extending between the inlet and the outlet; and
a piezoelectric element surrounding and in direct or indirect contact with the first hollow body;
wherein the first hollow body is a composite body formed from at least:
an outer support portion formed from metal; and
an inner portion formed from a glass material and supported by the outer support portion.

18. The fuel droplet nozzle assembly of claim 17, wherein the inner portion is supported by the outer support portion along an entire axial extent of the inner portion.

19. The fuel droplet nozzle assembly of claim 17, wherein a thickness of the outer support portion is the same as or greater than a thickness of the inner portion.

20. A fuel droplet nozzle assembly comprising:
a first hollow body comprising an inlet and an outlet and a bore extending between the inlet and the outlet; and
a piezoelectric element surrounding and in direct or indirect contact with the first hollow body;
wherein the piezoelectric element comprises a hollow frustoconical body and at least a portion of an external surface of the first hollow body is generally frustoconical.

21. The fuel droplet nozzle assembly of claim 17, wherein the inner portion comprises a glass tube and/or wherein the inner portion comprises:
a first glass section defining the inlet; and
a second glass section defining the outlet.

22. The fuel droplet nozzle assembly of claim 17, wherein an outer surface of the inner portion and an inner surface of the outer support portion are shaped such that a pressure difference between a first region in fluid communication with the inlet and a second region in fluid communication with the outlet urges the inner and outer support portions together.

23. The fuel droplet nozzle assembly of claim 17, wherein a plurality of slits are defined on an external surface of the first hollow body, the plurality of slits extending in a direction generally parallel to the bore and extending partially radially inwards into the first hollow body.

24. The fuel droplet nozzle assembly of claim 17, further comprising a second hollow body surrounding and in direct or indirect contact with the piezoelectric element.

25. The fuel droplet nozzle assembly of claim 24, wherein the piezoelectric element comprises a hollow cylindrical body,
wherein the second hollow body comprises a first portion having a cylindrical bore for receipt of the piezoelectric element and a generally frustoconical external surface,
wherein the second hollow body further comprises a second portion surrounding the first portion, and
wherein at least a portion of an internal surface of the second portion is generally frustoconical and complementary to the external surface of the first portion.

26. The fuel droplet nozzle assembly of claim 24, wherein the second hollow body comprises a portion having a generally frustoconical internal surface adjacent an external surface of either the piezoelectric element or the first portion of the second hollow body.

27. A droplet generator assembly comprising:
a fuel reservoir; and
a fuel droplet nozzle assembly of claim 17, and
wherein the fuel reservoir is in fluid communication with the inlet of the first hollow body.

28. The droplet generator assembly of claim 17, further comprising a power supply arranged to apply an excitation voltage across an outer surface and an inner surface of the piezoelectric element, the droplet generator assembly, further comprising a controller operable to control the excitation voltage applied by the power supply.

29. The droplet generator assembly of claim 27, wherein the power supply is configured to apply a periodic excitation voltage having an excitation frequency that generally matches a resonant frequency of a fuel within the bore.

30. The droplet generator assembly of claim 27, wherein the piezoelectric element is disposed such that a center of the piezoelectric element in a direction parallel to the bore generally coincides with an anti-node of a resonant mode of a fuel within the bore.

31. A laser produced plasma radiation source comprising the droplet generator assembly of claim 28.

32. A lithographic system comprising the laser produced plasma radiation source of claim 31.
